(19) United States
(12) Patent Application Publication
(10) Pub. No.: US 2009/0284918 A1
(43) Pub. Date: Nov. 19, 2009

(54) ELECTRONIC DEVICE WITH PHONONIC CRYSTAL STRUCTURE

(75) Inventor: Tai-Hsu Chou, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: HON HAI PRECISION INDUSTRY CO., LTD., Tu-Cheng (TW)

(21) Appl. No.: 12/345,886

(22) Filed: Dec. 30, 2008

(30) Foreign Application Priority Data
May 16, 2008 (CN) 200810301613.3

(51) Int. Cl. H05K 7/20

(52) U.S. Cl. 361/695

(57) ABSTRACT

An exemplary electronic device includes a housing and a plurality of parallel bars. The housing defines a chamber therein and a heat-dissipating opening at one side thereof. The bars are configured for abating noises, and are received in the chamber and adjacent to the heat-dissipating opening. The bars are arranged in a two-dimensional crystal lattice.

### BACKGROUND

1. Technical Field

The present invention relates to an electronic device with a phononic crystal structure.

2 Description of Related Art

Many kinds of electronic devices, such as projectors, personal computers, have been widely used in daily life. Electronic devices usually employ a fan to dissipate heat. Generally, the fan generates a loud noise during functioning, which makes cause discomfort to the users.

Therefore, a new electronic device is desired to overcome the above mentioned problems.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic, isometric view of an electronic device according to an exemplary embodiment.

FIG. 2 is a cross-sectional view of the electronic device of FIG. 1, taken along the line II-II thereof.

FIG. 3 is an exploded view of the electronic device of FIG. 1.

FIG. 4 is a cross-sectional view of a phononic crystal structure employed in the electronic device of FIG. 1.

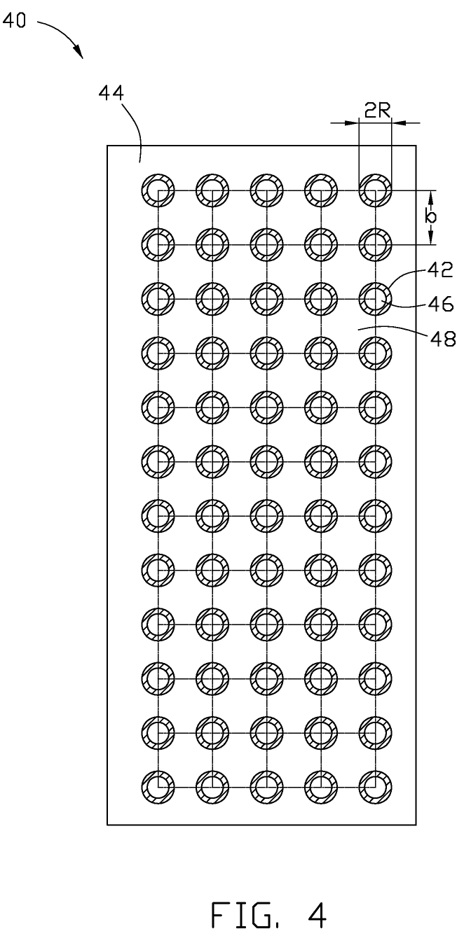

### DETAILED DESCRIPTION OF THE EMBODIMENTS

Embodiments will now be described in detail below with reference to the drawings.

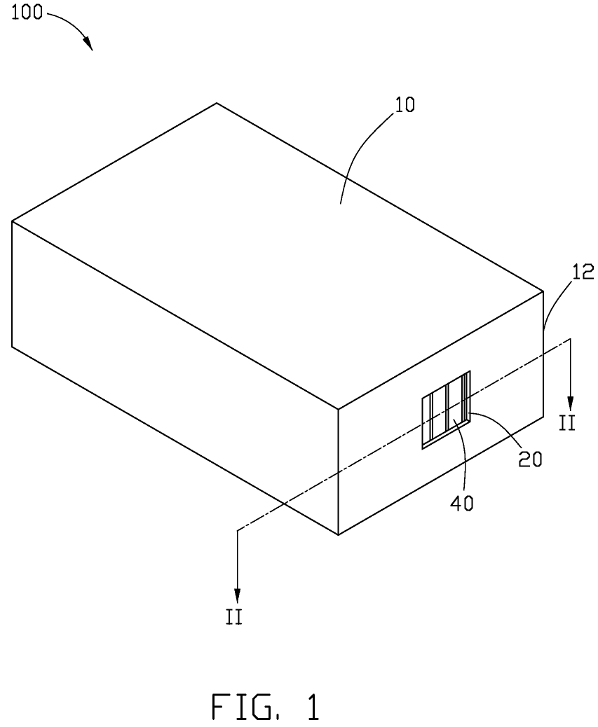

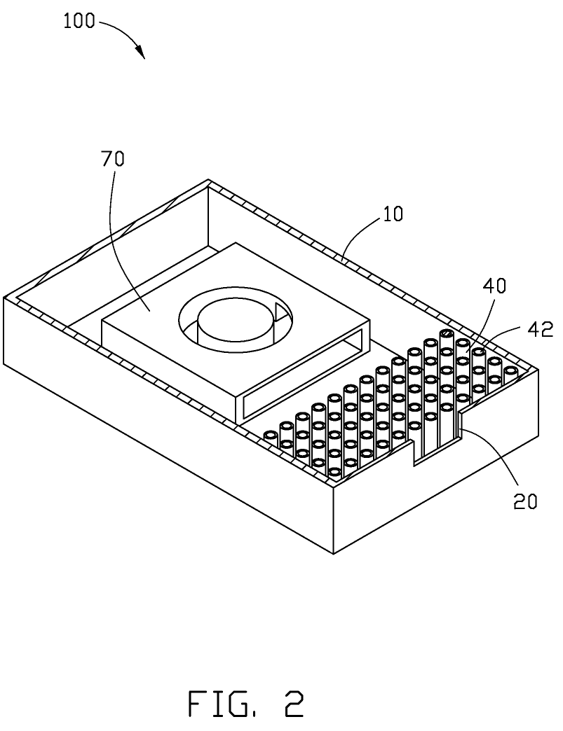

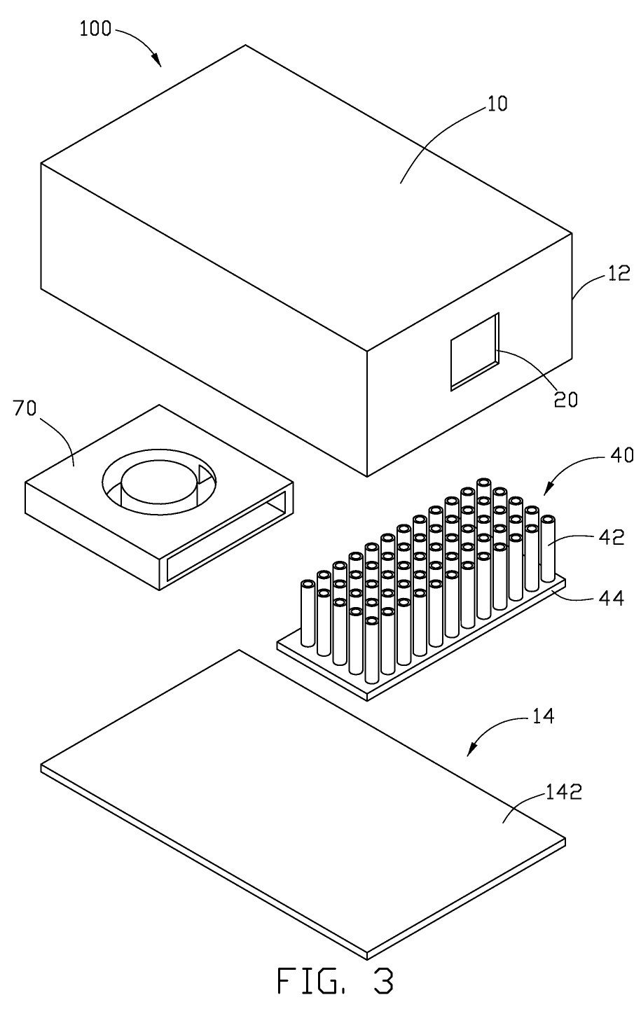

Referring to FIGS. 1-3, an electronic device 100 in accordance with an exemplary embodiment is shown. The electronic device 100 includes a housing 10, a fan 70 and a two-dimensional phononic crystal structure 40. Other electronic components of the electronic device 100 are not shown.

The housing 10 includes a bottom plate 14, a side plate 12 connected with the bottom plate 14. The bottom plate 14 includes a surface 142. The side plate 12 defines a heat-dissipating opening 20 therein.

The fan 70 is disposed on the surface 142 of the bottom plate 14 and is received in the housing 10. The fan 70 is configured for dissipating heat from the electronic device 10.

The phononic crystal structure 40 is formed on the surface 142 of the bottom plate 14. The phononic crystal structure 40 is positioned between the fan 70 and the side plate 12, and is adjacent to the heat-dissipating opening 20. The phononic crystal structure 40 is configured for abating noises (i.e., reducing an intensity of the noises) generated by electronic components (for example, the fan 70) within the electronic device 100.

The phononic crystal structure 40 includes a substrate 44 and a plurality of bars 42 extending from the substrate 44. The substrate 44 is fixedly mounted on the surface 142 of the bottom plate 14. The bars 42 are periodically arranged in a two-dimensional crystal lattice. In the present embodiment, the two-dimensional crystal lattice includes a plurality of interconnected squares in an array. A lattice constant of crystal lattice is a length b of a side of the square.

Each of the bars 42 has a central axis (not shown), and each central axis is substantially perpendicular to the surface 142 of the bottom plate 14. Each bar 42 can be circular, elliptical, square, or regular hexagonal in cross-section. In the present embodiment, each bar 42 is circular in cross-section. Whether each bar 42 is hollow or not does not affect the efficiency of abating the noises of the phononic crystal structure 40. Accordingly, in the present embodiment, each bar 42 is hollow, so that less material is used in the phononic crystal structure 40 and the cost is decreased. Each bar 42 is comprised of iron, stainless steel, or aluminum alloy.

An outer diameter of each bar 42 is 2 R, and a filling ratio f of the phononic crystal structure 40 can be calculated according to the following equation: f=πR²/b². When the filling ration f is large, the phononic crystal structure 40 can abate the noise with a high frequency. It is to be noted that the phononic crystal structure 40 can further include a plurality of bars (not shown) arranged in a two-dimensional crystal lattice with a lattice constant different from the lattice constant b, so that the noises with a wide frequency range can be abated by the phononic crystal structure 40.

It should be noted that the substrate 44 and the plurality of bars 42 can be formed integrally. It should also be noted that the substrate 44 of the phononic crystal structure 40 can be eliminated and the plurality of bars 42 are directly formed on the surface 142 of the bottom plate 14.

The phononic crystal structure 40 abates most of the noises in the electronic device 100. As a result, the electronic device 100 is quiet when in operation. Furthermore, a gap between adjacent bars facilitates heat-dissipating via the heat-dissipating opening 20.

While certain embodiments have been described and exemplified above, various other embodiments from the foregoing disclosure will be apparent to those skilled in the art. The present invention is not limited to the particular embodiments described and exemplified but is capable of considerable variation and modification without departure from the scope of the appended claims.

What is claimed is:

1. An electronic device comprising:
a housing comprising a bottom plate and a side plate connected with the bottom plate, the bottom plate having a surface, the side plate having a heat-dissipating opening defined therein;
a fan disposed on the surface of the bottom plate and received in the housing; and
a two-dimensional phononic crystal structure formed on the surface of the bottom plate, the phononic crystal structure configured for reducing noises generated by the fan, the phononic crystal structure being positioned between the fan and the side plate and adjacent to the heat-dissipating opening, the phononic crystal structure comprising a plurality of parallel bars arranged in a two-dimensional crystal lattice, each of the bars having a central axis, each central axis being substantially perpendicular to the surface of the bottom plate.

2. The electronic device of claim 1, wherein the two-dimensional crystal lattice is square.

3. The electronic device of claim 1, wherein each of the bars is circular, elliptical, square, or regular hexagonal in cross-section.

4. The electronic device of claim 1, wherein each of the bars is hollow.

5. The electronic device of claim 1, wherein each of the bars is comprised of a material selected from the group consisting of iron, stainless steel, and aluminum alloy.

6. An electronic device comprising:
a housing defining a chamber therein and a heat-dissipating opening at one side thereof, and
a plurality of parallel bars configured for reducing noises, the bars being received in the chamber and being adjacent to the heat-dissipating opening, the plurality of bars being arranged in a two-dimensional crystal lattice.

7. The electronic device of claim 6, wherein the two-dimensional crystal lattice is square.

8. The electronic device of claim 6, wherein each of the bars is circular, elliptical, square, or regular hexagonal in cross-section.

9. The electronic device of claim 6, wherein each of the bars is hollow.

10. The electronic device of claim 6, wherein each of the bars is comprised of a material selected from the group consisting of iron, stainless steel, and aluminum alloy.
